(19) United States
(12) Patent Application Publication
(10) Pub. No.: US 2024/0105535 A1
(43) Pub. Date: Mar. 28, 2024

(54) SEMICONDUCTOR DEVICE AND METHOD FOR PRODUCING SEMICONDUCTOR DEVICE

(71) Applicant: Mitsubishi Electric Corporation, Tokyo (JP)

(72) Inventor: Koji YAMAZAKI, Tokyo (JP)

(73) Assignee: Mitsubishi Electric Corporation, Tokyo (JP)

(21) Appl. No.: 18/275,405

(22) PCT Filed: Mar. 17, 2021
(86) PCT No.: PCT/JP2021/010785

§ 371 Date: Aug. 2, 2023

(51) Int. Cl. H01L 23/31; H01L 21/56; H01L 23/00

(52) U.S. Cl. CPC H01L 23/3107; H01L 21/565; H01L 24/32; H01L 2224/32225

(57) ABSTRACT

In this semiconductor device, a terminal having a first metal electrode portion at an upper surface is joined via a first joining material to an upper surface of a semiconductor element. The terminal and the semiconductor element are sealed by a sealing material so that an upper surface of the first metal electrode portion is exposed. The upper surface of the first metal electrode portion is connected via a second joining material to a lower surface of a second metal electrode portion formed at a lower surface of a circuit board. Slopes are provided on an upper surface of the sealing material so that vertical-direction height at the first metal electrode portion is the largest and vertical-direction height at an end of the sealing material is low.

### TECHNICAL FIELD

The present disclosure relates to a semiconductor device and a method for producing the semiconductor device.

### BACKGROUND ART

In semiconductor elements, a base material made of silicon (Si) or gallium arsenide (GaAs) is often used, and the operation temperature is 100° C. to 125° C. A material for bonding these elements to a circuit board is required to have a crack resistance against repetitive occurrences of thermal stress due to start and stop at a high melting point. To satisfy this requirement, 95Pb-5Sn (mass %) has been used in a Si device, and 80Au-20Sn (mass %) or the like has been used in a gallium arsenide device. However, 95Pb-5Sn containing a large amount of lead (Pb) which is harmful has a problem in terms of reduction in the load on the environment. In addition, 80Au-20Sn containing a large amount of noble metal has a problem in terms of a high price of noble metal and a less reserve thereof. Accordingly, materials alternative to these have been highly desired.

Meanwhile, from the standpoint of energy saving, devices using silicon carbide (SiC) or gallium nitride (GaN) as a base material are increasingly developed as next-generation devices. From the standpoint of loss reduction of power consumption, the operation temperature of these devices is set to 175° C. or higher and is expected to reach 300° C. in the future. Therefore, a joining part at the lower surface of a semiconductor element is required to have high heat dissipation property and high joining reliability.

As a material having high heat dissipation property and high joining reliability, a joining material using a conductive composition containing a particulate metal compound is known. In particular, a typical metal is Ag, and it is known that, in an Ag nanoparticle formed by reducing the particle size of Ag to 100 nm or less, the number of constituent atoms is decreased, so that the ratio of the surface area to the volume of the particle sharply increases, whereby the melting point and the sintering temperature are significantly reduced as compared to a bulk state. By utilizing this low-temperature sintering function, metal particles whose surfaces are coated with organic matter and which have an average particle size of 100 nm or less are used as a joining material. And the organic matter is decomposed, and the metal particles are sintered closely to each other. For this purpose, it is necessary to apply a pressure in addition to heating, at the time of joining. When a pressure is applied, the sintering density increases, so that the heat dissipation property and the joining reliability are improved. But at this time, the semiconductor element might be damaged.

Here, in a case in which one semiconductor element is joined to one circuit board and the semiconductor element is damaged by the pressure, it is enough that only the one semiconductor element is discarded. However, in a case in which a plurality of semiconductor elements are simultaneously joined to one circuit board for the purpose of reducing the size and increasing the density, if only one of the semiconductor elements is damaged, all the semiconductor elements joined to the circuit board, including the remaining normal ones, must be discarded. Thus, there is a problem that the yield is lowered. In particular, the element cost is higher for SiC or GaN than for Si or GaAs, and therefore improving the yield is an important problem in production.

Patent Document 1 discloses a semiconductor device having such an insulation substrate that a semiconductor chip having a semiconductor element is embedded in insulating resin, and including main wiring formed at the surface of the insulation substrate and connected to a main electrode of the semiconductor chip through a via hole, sub wiring formed at the surface of the insulation substrate and connected to a sob electrode of the semiconductor chip through a via hole, and a metal plate connected to the surface of the main wiring via a conductive adhesive. The sub wiring has a section in which the wiring width is smaller than the wiring width of the main waring (see Patent Document 1 below).

### PRIOR TECHNICAL DOCUMENTS

### Patent Document

Patent Document 1: Japanese Laid-Open Patent Publication No. 2015-005681

### SUMMARY OF THE INVENTION

### Problems to be Solved by the Invention

In Patent Document 1, in order to achieve size reduction, semiconductor elements embedded in an insulating resin via the metal plate are connected by the conductive adhesive through via holes to each other. However, in performing joining by the conductive adhesive at a narrow space between the metal plate and the semiconductor element, a volatile component generated when the adhesive is cured is hardly discharged to outside. And the adhesion effect is insufficient, thus a problem of adhesion fault occurs. In a case of joining the joining part by general solder paste, in the same manner as the case of the adhesive, an organic component contained in the paste is hardly discharged to outside when vaporizing, thus a problem of adhesion fault occurs. In a case of using a solder sheet and performing joining under a formic acid (CH₂O₂) reduction atmosphere, formic acid reduction gas hardly enters a narrow gap. In addition, joining fault is likely to occur due to foreign maters and the like adhered to members, so that the productivity and the yield are lowered on the contrary. Further, if a joining layer is thickened, there is a problem that the cost of the joining material increases and size reduction cannot be achieved.

The present disclosure has been made to solve the above problems, and an object of the present disclosure is to prevent joining fault between parts composing a semiconductor device.

### Means to Solve the Problems

A semiconductor device according to the present disclosure is a semiconductor device, wherein a terminal having a first metal electrode portion at an upper surface thereof is joined via a first joining material to an upper surface of a semiconductor element, the terminal and the semiconductor element are sealed by a sealing material such that an upper surface of the first metal electrode portion is exposed, the upper surface of the first metal electrode portion is connected via a second joining material to a lower surface of a second metal electrode portion formed at a lower surface of a circuit board, and a slope is provided on an upper surface of the sealing material so that a vertical-direction height at the first metal electrode portion is the largest and a vertical-direction height at an end of the sealing material is low.

A method for producing a semiconductor device according to the present disclosure includes the steps of: placing, at an inside between a lower die and an upper die having a slope at an upper part thereof, such a unit that a terminal having a first metal electrode portion at an upper surface thereof is joined via a first joining material to an upper surface of a semiconductor element; injecting a sealing material to the inside between the lower die and the upper die; and removing the upper die and the lower die and connecting an upper surface of the first metal electrode portion via a second joining material to a lower surface of a second metal electrode portion formed at a lower surface of a circuit board.

### Effect of the Invention

The semiconductor device and the method for producing the semiconductor device according to the present disclosure can prevent joining fault between parts composing the semiconductor device.

### BRIEF DESCRIPTION OF THE DRAWINGS

FIG. 1 is a flowchart showing a process fox producing a semiconductor device according to embodiment 1.

FIG. 2 is a side sectional view showing the semiconductor device according to embodiment 1.

FIG. 3 is a side sectional view showing the semiconductor device according to embodiment 1.

FIG. 4 is a side sectional view showing a sealing process according to embodiment 1.

FIG. 5 is a side sectional view showing the sealing process according to embodiment 1.

FIG. 6 is a side sectional view showing the sealing process according to embodiment 1.

FIG. 7 is a side sectional view showing the sealing process according to embodiment 1.

FIG. 8 is a side sectional view showing the semiconductor device according to embodiment 1.

FIG. 9 is a side sectional view showing the semiconductor device according to embodiment 1.

FIG. 10 is a side sectional view showing the sealing process according to embodiment 1.

FIG. 11 is a side sectional view showing the sealing process according to embodiment 1.

FIG. 12 is a side sectional view showing the sealing process according to embodiment 1.

FIG. 13 is a side sectional view showing the sealing process according to embodiment 1.

FIG. 14 is a side sectional view showing the semiconductor device according to embodiment 1.

FIG. 15 is a side sectional view showing the semiconductor device according to embodiment 1.

FIG. 16 is a side sectional view showing a semiconductor device in a comparative example.

FIG. 17 is a side sectional view showing the semiconductor device in the comparative example.

FIG. 18 is a side sectional view showing the semiconductor device in the comparative example.

FIG. 19 is a table showing the angle of each slope, a void fraction, and a judgment result.

FIG. 20A shows a SAT image in comparative example 1 (θ=0°).

FIG. 208 shows a SAT Image in comparative example 2 (θ=0.8°).

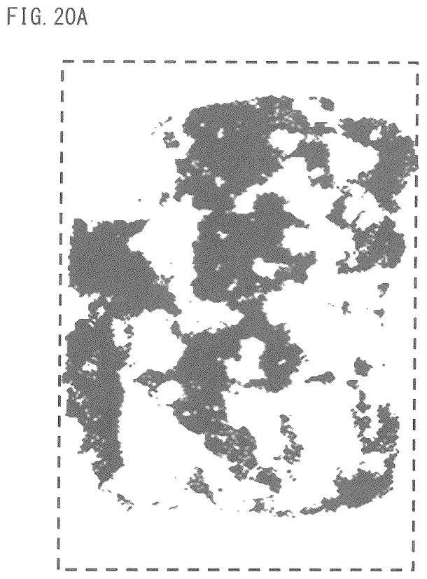

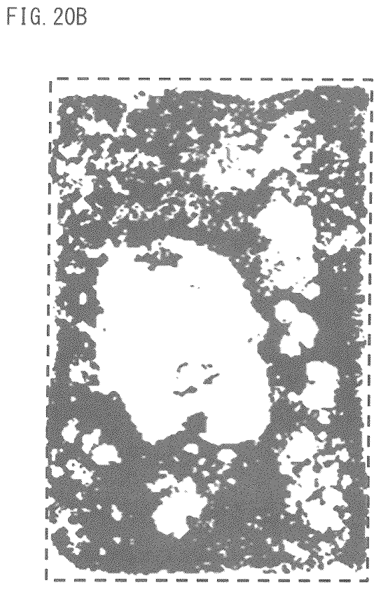

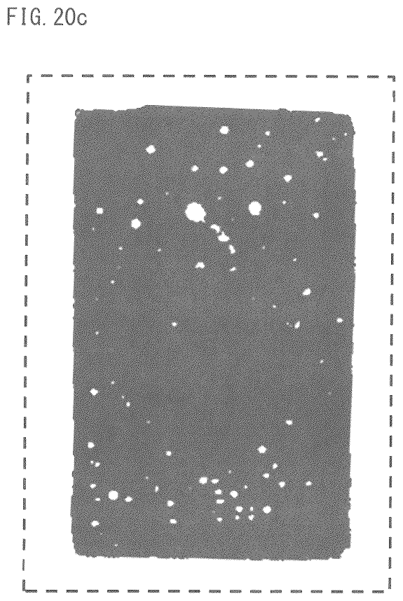

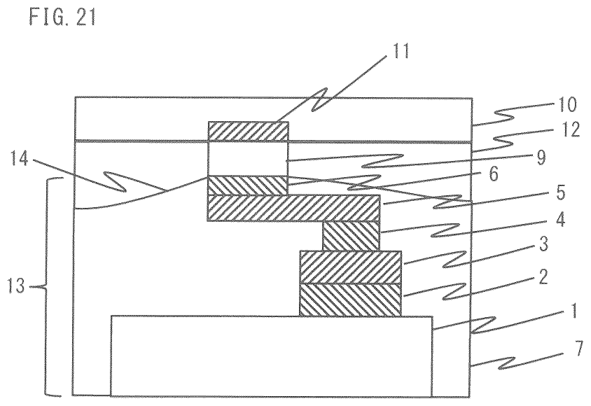

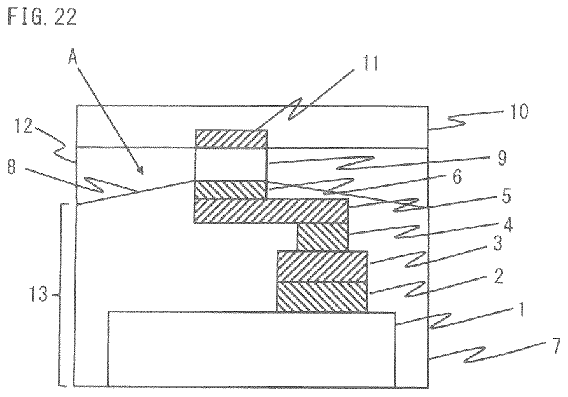

FIG. 20C shows a SAT image in example 1 (θ=1°).

FIG. 21 is a side sectional view showing a semiconductor device according to embodiment 2.

FIG. 22 is a side sectional view showing the semiconductor device according to embodiment 2.

FIG. 23 is a plane view of a sealing material in FIG. 22, as seen from a direction A.

### EMBODIMENTS FOR CARRYING OUT THE INVENTION

### Embodiment 1

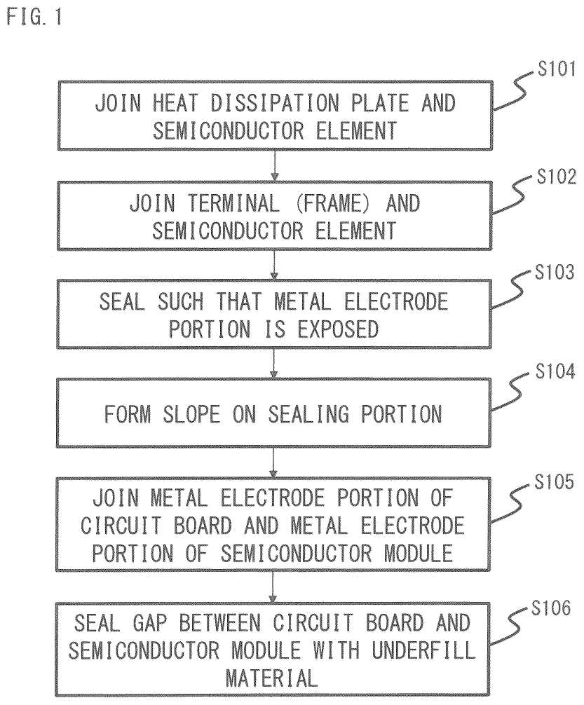

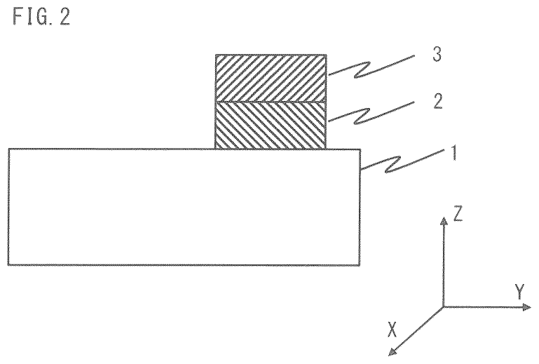

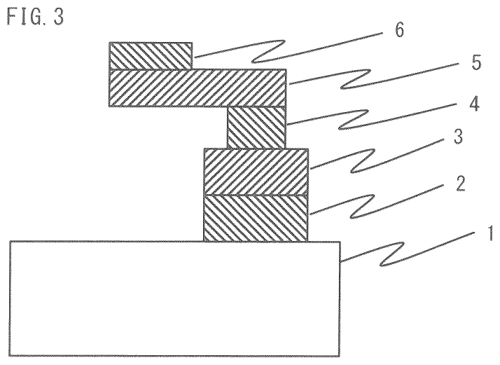

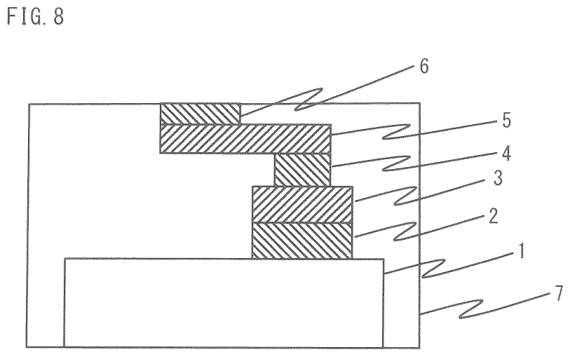

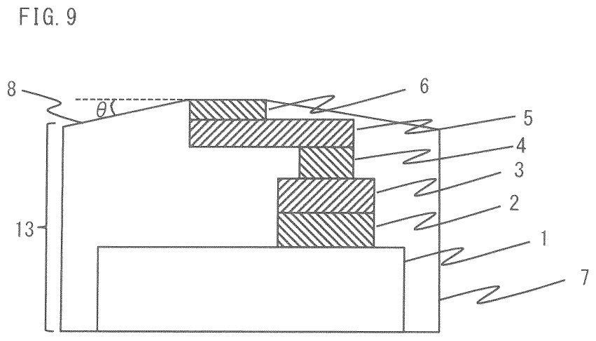

The present embodiment relates to a structure of a joining body of a semiconductor element to be used for an electronic device or the like, and a method for producing the joining body. FIG. 1 is a flowchart showing a process for producing a semiconductor device according to embodiment 1, and FIG. 2, FIG. 3, FIG. 8, and FIG. 9 are side sectional views showing the semiconductor device. In the drawings, an X direction and a Y direction perpendicular to the X direction are horizontal directions, and a Z direction perpendicular to the X direction and the Y direction is a vertical direction. In FIG. 2, the arrow side in the Z direction is defined as an upward direction and an upper side, and the side opposite to the arrow side is defined as a downward direction and a lower side. In boards and the like described below, a surface on the upper side is defined as an upper surface, and a surface on the lower side is defined as a lower surface. Also in FIG. 3 and subsequent figures, the same definition is applied.

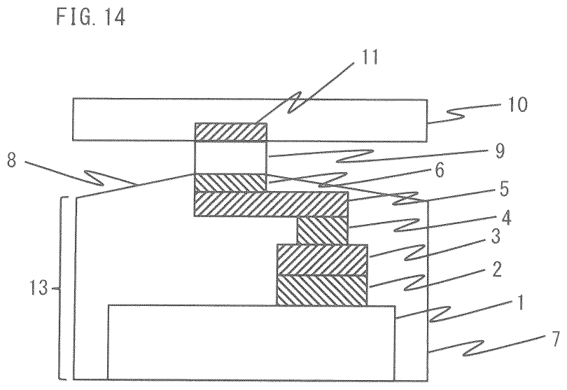

The purpose of the present embodiment is to finally produce a semiconductor device as shown in FIG. 14 described later. That is, the semiconductor device according to the present embodiment is formed by joining a semiconductor element 3 to an upper surface of a heat dissipation plate 1 by a sintering Ag joining material 2. A terminal 5 is joined to an upper surface of the semiconductor element 3 via a solder material 4 (first joining material), and a metal electrode portion 6 (first metal electrode portion) is provided on an upper surface of the terminal 5. Then, the heat dissipation plate 1, the terminal 5, and the semiconductor element 3 are sealed by a sealing material 7 such that an upper surface of the metal electrode portion 6 is exposed. Further, the upper surface of the metal electrode portion 6 is joined to a lower surface of a metal electrode portion 11 (second metal electrode portion) via a solder material 9 (second joining material), and the metal electrode portion 11 is formed at a lower surface of a circuit board 10. Hereinafter, a process for producing the semiconductor device as described above will be described.

First, in a first step (step S101) in FIG. 1, as shown in FIG. 2, the semiconductor element 3 is joined to the upper surface of the heat dissipation plate 1 by the sintering Ag joining material 2. As the heat dissipation plate 1, a tough-pitch copper plate having a size of 20 mm×20 mm and a thickness of 3 mm is used. As the semiconductor element 3, a SiC chip having a size of 5 mm×5 mm and a thickness of 300 μm is used. On joining surfaces at the upper and lower surfaces of the semiconductor element 3, metal films of Ti, Ni, and Au are layered sequentially (topmost layer is Au film). The film thicknesses are 100 nm for Ti, 700 nm for Ni, and 200 am for Au.

Copper of the heat dissipation plate 1 is plated by Ag at 1 μm. In joining of the semiconductor element 3, as a sintering Ag paste which is the sintering Ag joining material 2, a typical material “CT2700R7S” manufactured by KYOCERA corporation is applied in an appropriate amount to a joining part, and joining is performed by applying a pressure of 10 MPa (N/mm²) per unit area with respect to a chip size, at 250° C. for ten minutes. In a case in which a solvent that reduces an oxide film of Cu or Ni is contained in the sintering Ag paste, it is not required to provide Au in the topmost layer of the semiconductor element 3 and the Ag plating of the surface of the heat dissipation plate 1.

Next, in a second step (step S102), as shown in FIG. 3, the terminal 5 (frame) having the metal electrode portion 6 (first metal electrode portion) at the upper surface is joined via the solder material 4 (first joining material) to the upper surface of the semiconductor element 3 joined on the vertical-direction upper side of the heat dissipation plate 1 by the sintering Ag joining material 2. As the solder material 4, a sheet of Sn-5Sb (which has such a solder composition that 5 wt % of Sb is contained in Sn and has a melting point of 243° C.) having a thickness of 300 μm may be used. With this sheet cut in an appropriate size, joining may be performed under a formic acid reduction atmosphere at a joining temperature of 260° C. for ten minutes.

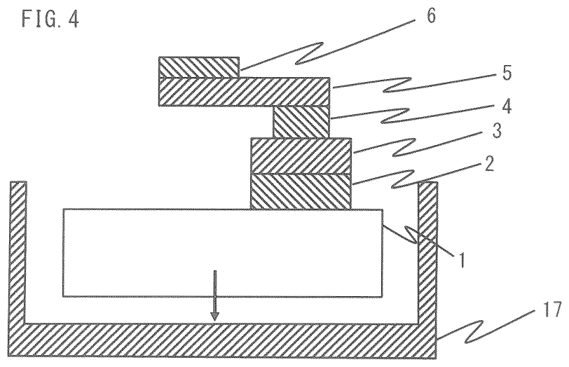

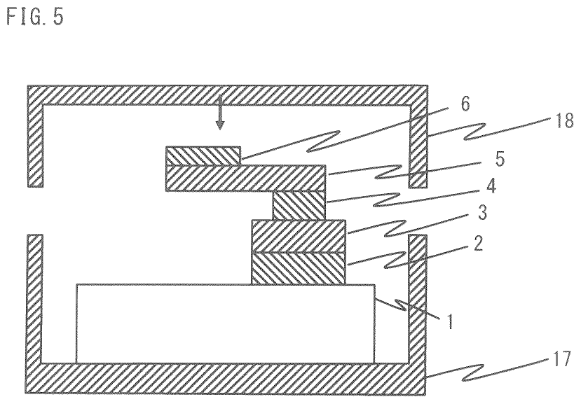

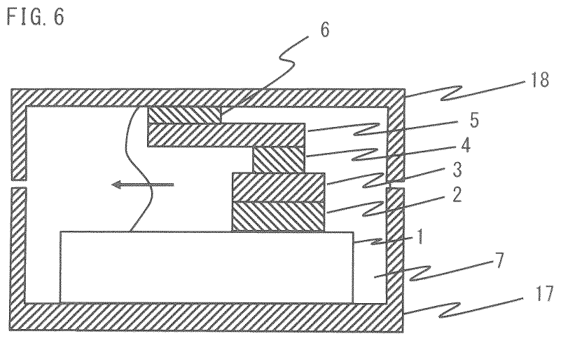

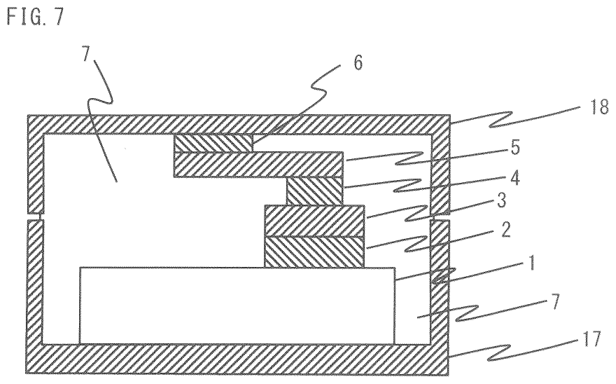

Next, in a third step (step S103), the heat dissipation plate 1, the sintering Ag joining material 2, the semiconductor element 3, the colder 4, and the terminal 5 are sealed by the epoxy-based sealing material 7 such that the metal electrode portion 6 of the terminal 5 is exposed. FIG. 4 to FIG. 7 are side sectional views showing a sealing process. First, as shown in FIG. 4, a lower die 17 is prepared, and such a unit that the terminal 5 is joined via the solder material 4 above the semiconductor element 3 joined above the heat dissipation plate 1 by the sintering Ag joining material 2 as shown in FIG. 3 is disposed into the lower die 17. Next, as shown in FIG. 5, the lower die 17 and an upper die 18 are fitted to each other and the upper and lower dies are closed, so that the unit shown in FIG. 3 is placed inside. Next, as shown in FIG. 6, the sealing material 7 is injected into the mold. FIG. 6 shows a state in which the sealing material 7 is injected toward the left side from the right side on which an injection port is present, as indicated by an arrow, and shows a state during injection. As the sealing material 7, phenolic resin curing agent based-resin or epoxy resin containing silica particles (the thermal expansion coefficient of the resin is 12 ppm/K) may be used. The members can be sealed by injecting the sealing material 7 into the mold under a condition (such as a pressure) matching the sealing material. Next, as shown in FIG. 7, a curing process for the sealing material 7 is performed in a state in which the members are sealed in the mold. For example, the curing process condition is a condition in which the temperature is 180° C. and the time is three minutes. Further, the upper die 18 and the lower die 17 are removed, and a curing process for the sealing material is performed again at 175° C. for six hours. Thus, as shown in FIG. 8, the heat dissipation plate 1, the sintering Ag joining material 2, the semiconductor element 3, the solder material 4, and the terminal 5 are sealed by the epoxy-based sealing material 7 such that the upper surface of the metal electrode portion 6 of the terminal 5 is exposed.

Next, in a fourth step (step S104), as shown in FIG. 9, on the vertical-direction upper-side surface (upper surface) of the sealing material 8 in a sealed and integrated semiconductor module 13, slopes 8 are formed through grinding so that the vertical-direction height at the metal electrode portion 6 is large and ends of the sealing material 7 are low. As a method for forming the slopes 8 other than grinding, slopes may be formed in advance in the die used in the third step, and the slopes 8 may be formed by molding. Regarding the angle of the slopes 8, it is desirable that an angle θ (see FIG. 9) with respect to the horizontal direction is set to be not less than 1° and not greater than 10° so that the height at the metal electrode portion 6 is the largest and the ends ace low.)

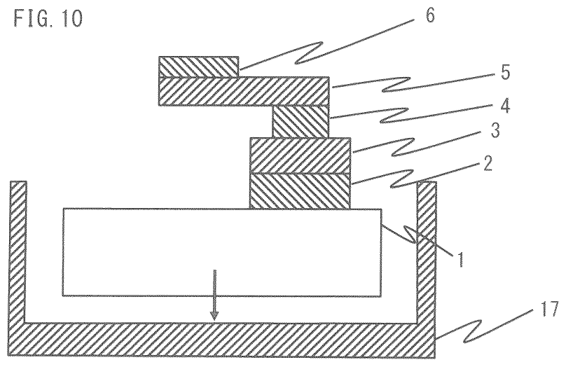

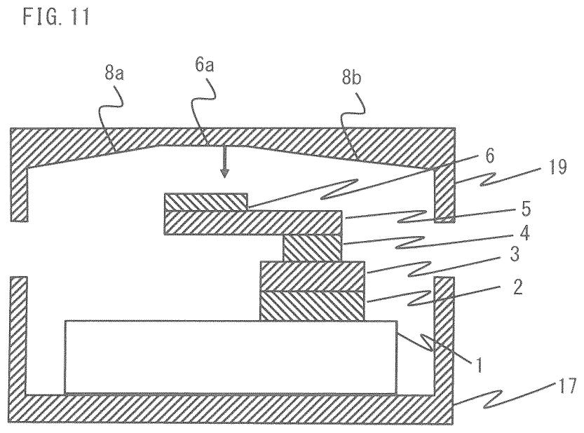

In the step of forming the slopes 8 in the fourth step (form slopes at sealing portion), instead of forming the slopes 8 by grinding, a case of providing slopes in a die in advance at a time of performing sealing such that the metal electrode portion 6 is exposed will be described with reference to FIG. 10 to FIG. 13. First, as shown in FIG. 10, the lower die 17 is prepared, and such a unit that the terminal (frame) 5 is joined via the solder material 4 above the semiconductor element 3 joined above the heat dissipation plate 1 by the sintering Ag joining material 2 as shown in FIG. 10 is disposed into the lower die 17. Next, as shown in FIG. 11, the lower die 17 and an upper die 19 having slopes 8a, 8b at an upper inner surface are fitted to each other and the upper and lower dies are closed, so that the unit shown in FIG. 3 is placed inside. The slopes 8a, 8b are parts corresponding to the slopes 8, and a horizontal portion 6a is a part corresponding to the upper surface of the metal electrode portion 6.

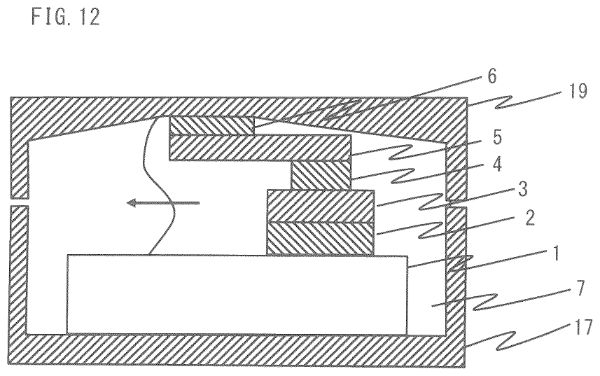

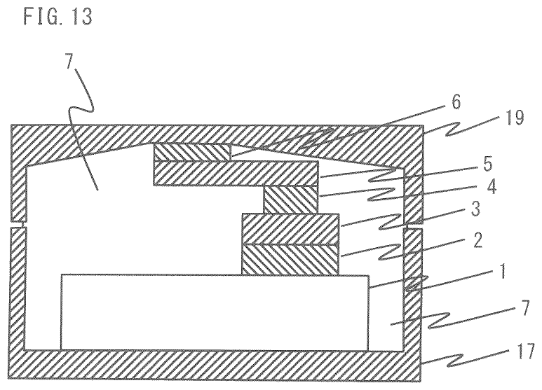

Next, as shown in FIG. 12, the sealing material 7 is injected into the mold. FIG. 12 shows a state in which the sealing material 7 is injected toward the left side from the right side on which an injection port is present, as indicated by an arrow, and shows a state during injection. As the sealing material 7, phenolic resin curing agent based-resin ox epoxy resin containing silica particles (the thermal expansion coefficient of the resin is 12 ppm/K) may be used. The members can be sealed by injecting the sealing material 7 into the mold under a condition (such as a pressure) matching the sealing material. Next, as shown in FIG. 13, a curing process for the sealing material 7 is performed in a state in which the members are sealed in the mold. For example, the curing process condition is a condition in which the temperature is 180° C. and the time is three minutes. Further, the upper die 19 and the lower die 17 are removed, and a curing process for the sealing material is performed again at 175° C. for six hours. Thus, the semiconductor module shown in FIG. 9 is obtained.

As the metal electrode portion 6 and the terminal (frame) 5, tough-pitch copper, oxygen-free copper, or a lamination of Cu/Invar/Cu may be used in view of conductivity and ease of working of the material. Alternatively, a copper-zinc alloy, a copper-tin alloy, of a copper-chromium alloy, containing copper as a main component, may be used in order to suppress copper leaching (dissolution) at the time of solder joining. Still alternatively, plating ox an alloy containing, as a main component, nickel which is less leached than copper, may be used.

Next, in a fifth step (step S105), as shown in FIG. 14, the upper surface of the metal electrode portion 6 of the sealed and integrated semiconductor module 13 is joined via the solder material 9 (second joining material) to the lower surface of the metal electrode portion 11 (second metal electrode portion) formed at the lower surface of the circuit board 10. As the solder material 9, a solder sheet of Sn-3Ag-0.5Cu (which is such a solder composition that 3 wt % of Ag and 0.5 wt % of Cu are contained in Sn and has a melting point of 220° C.) may be used. The size of the metal electrode portion 6 of the semiconductor module 13 is 2 mm×3.3 mm, and the metal electrode portion 11 of the circuit board 10 also has the same size. Therefore, the size of the solder sheet as the solder material 9 is also 2 mm×3.3 mm, and the thickness of the solder material 9 is 50 μm.

Here, in order that the soldier material 4 in the semiconductor module 13 does not melt again at the time of performing joining by the solder material 9, the melting point of the solder material 4 needs to be higher than the melting point of the solder material 9. In addition, the joining temperature in this step needs to be lower than the melting point of the solder material 4 and higher than the melting point of the solder material 9. Thus, in solder joining in this step, the joining temperature needs to be not less than 220° C. but less than 243° C. Therefore, in this step, joining is performed at a joining temperature of 230° C. for ten minutes. As the metal electrode portion 11 of the circuit board 10, copper may be used. The material of the metal electrode portion 11 only has to allow solder to wet and spread over the material, and tough-pitch copper, oxygen-free copper, or a lamination of Cu/Invar/Co may be used in view of conductivity and ease of working of the material. Alternatively, a copper-zinc alloy, a copper-tin alloy, or a copper-chromium alloy, containing copper as a main component, may be used in order to suppress copper leaching at the time of solder joining. Still alternatively, plating or an alloy containing, as a main component, nickel which is less leached than copper, may be used.

As a joining method, joining may be performed under a formic acid reduction atmosphere, or an organic solderability preservative (OSP) treatment may be performed and joining may be performed by using a high-temperature tank under a nitrogen atmosphere. Alternatively, joining may be performed by using a vapor furnace containing mixture of Galden (registered trademark) and formic acid. Examples of Galden (registered trademark) products include Galden HT230 (bp=230° C., viscosity=4.4 cSt, density=1.82), which is a heat medium available from Solvay. It is possible to perform joining at a desired temperature by adjusting the boiling point of Galden such as HT230 having a boiling point of 230° C. in the vapor race. Regarding Galden, with accordance to the joining temperature, HT170 (bp=170° C.) or HT200 (bp=200° C.) may be mixed. In the vapor furnace, Galden is vaporized and heating can be uniformly performed irrespective of the heat capacity or the shape of each member. Further, since the formic acid is mixed, an OSP treatment and the like are not needed and joining can be performed at a temperature close to the melting point of the solder.

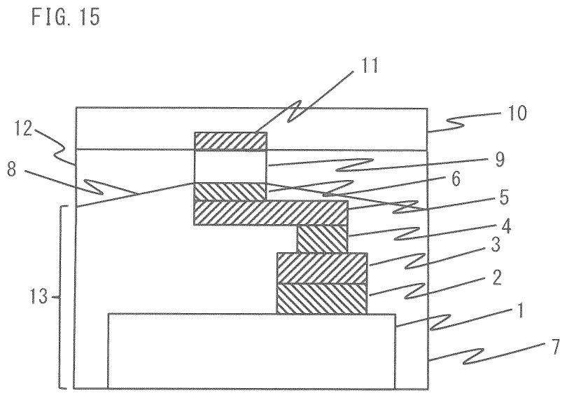

Next, in a sixth step (step S106), as shown in FIG. 15, the gap between the circuit board 10 and the semiconductor module 13 is sealed by being filled with an underfill material 12. Thus, the surrounding area of the joining part of the solder material 9 is also covered with an insolation material, whereby movement thereof can be prevented.

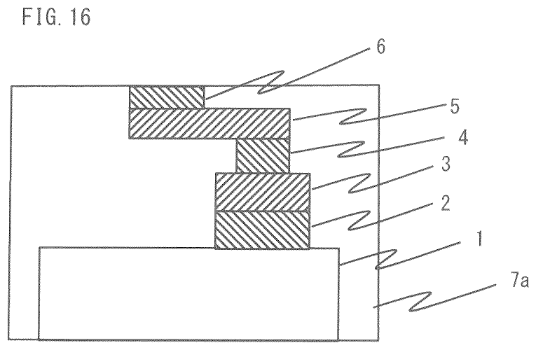

Next, the range of the angle θ of the slope 8 will be considered. Specifically, in order to produce a sample having no slopes as a comparative example, a case of performing joining under the same condition as described above except that slopes were not provided in the third and fourth steps, will be described with reference to FIG. 16 to FIG. 18. FIG. 16 to FIG. 18 are side sectional views showing a semiconductor device in the comparative example, FIG. 16 shows a state in which sealing was performed by a sealing material 7a such that the metal electrode portion 6 is exposed, without providing slopes.

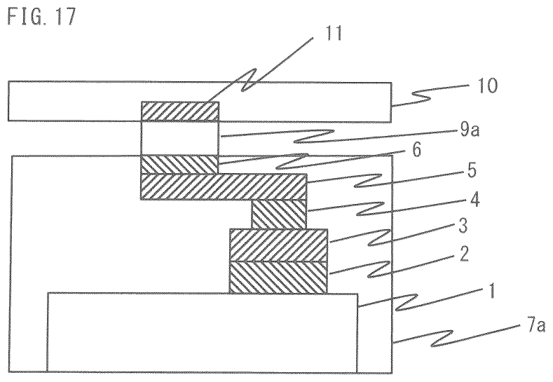

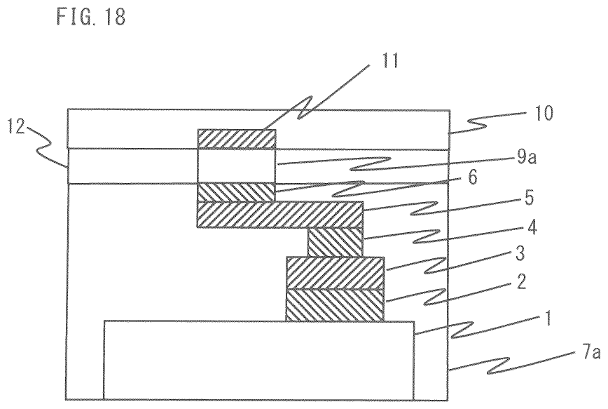

Next, in the same manner as the fifth step, as shown in FIG. 17, a solder material 9a is joined under the same condition as described above. Then, in the same manner as the sixth step, as shown in FIG. 18, the gap was filled with the underfill material 12 under the same condition as described above. Next, as shown in FIG. 16 to FIG. 18, the product having no slopes is defined as comparative example 1, a product in which the angle θ of the slopes 8 is set at 0.8° is defined as comparative example 2, a product in which the angle θ is set at 1° is defined as example 1, a product in which the angle θ is set at 5° is defined as example 2, and a product in which the angle θ is set at 10° is defined as example 3. Regarding the joining atmosphere, in order to heat uniformly, joining was performed at 230° C. for ten minutes in the above vapor furnace. After the joining, the joining parts of the solder materials 9, 9a were observed in a non-destructive manner by a scanning acoustic tomograph (SAT), and comparison was performed regarding voids in the joining parts, and non-joined arts. Fifty samples were produced for each product, and the first decimal places of values obtained by binarizing obtained images were rounded off, thus void fractions are calculated.

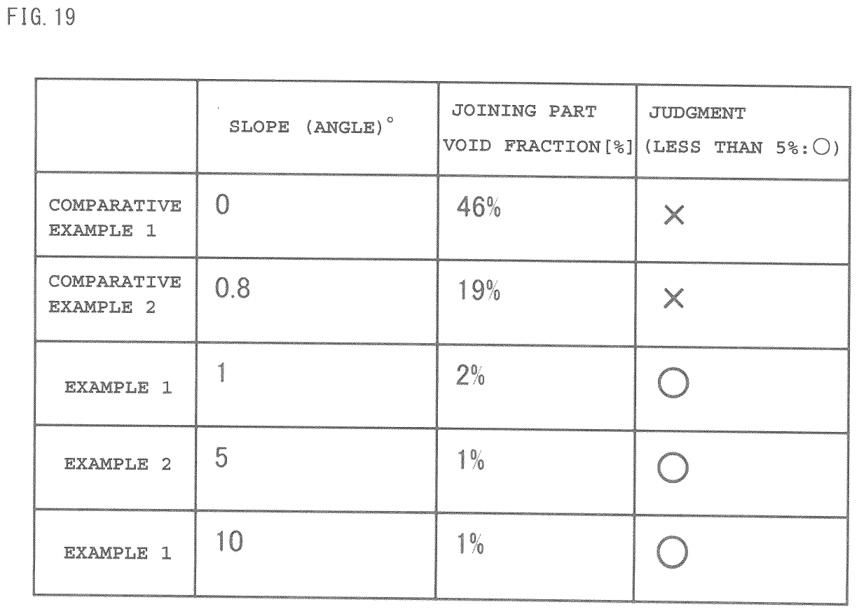

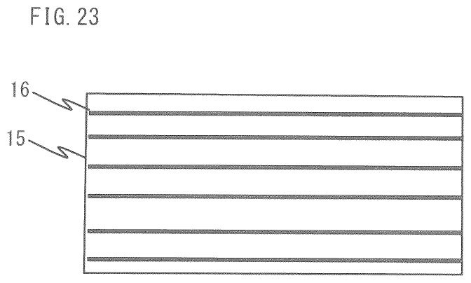

FIG. 19 is a table showing the void fraction at the joining part and the judgment result in comparative examples 1 and 2 and examples 1 to 3. In FIG. 19, as the void fraction, the highest value of void fractions in the fifty samples is shown. If the void fraction is less than 5%, it is judged that solder joining was normally made, and this product is judged to be acceptable (o), whereas if the void fraction is not less than 5%, this product is judged to be unacceptable (θ). As a result, as shown in FIG. 19, in comparative example 1 (θ=0°) and comparative example 2 (θ=0.8°), the void fractions are 46% and 19% which are larger than 5% which is an acceptable borderline, and therefore it is judged that they are unacceptable. Next, in example 1 (θ=1°), example 2 (θ=5°), and example 3 (θ=10°), the void fractions are 2%, 1%, and 1%, respectively, and thus, when the slope is not less than 1°, the amount of voids is small and favorable joining property is obtained. FIG. 20A to FIG. 20C show SAT images. FIG. 20A is a SAT image in comparative example 1 (θ=0°), FIG. 208 is a SAT image in comparative example 2 (θ=0.8°), and FIG. 20C is a SAT image in example 1 (θ=1°). As shown in FIG. 20A to FIG. 20C, it is found that the area occupied by the voids reduces as the angle increases from 0° to 0.8° and then 1.0°.

It is considered that, by providing the slopes as described above, the sizes of the openings of the side surfaces at the solder joining part become large and thus the vapor of the Galden and the formic acid gas effectively act on the solder joining part. In addition, it is considered that the slopes 8 has an effect of allowing the vapor of the Galden to expel contamination at each member or in the furnace from the joining part. In a case of an actual furnace for mass production, dirt and dust (contamination) adhered more or less to the members are accumulated inside the furnace, and they float and gather at a part in which convection stops in the furnace, through the formic acid or the Galden. In particular, at the joining part by the solder material 9, the gap has to become small in order to achieve size reduction and the surrounding contamination gathers. Thus, the joining part is a part in which the solder takes in the surrounding contamination when melting and wetting so that joining fault is likely to occur.

Accordingly, it has been found that the slopes 8 has a novel effect of preventing stop of convection and stably expelling the surrounding dust from the solder joining part, thus joining fault is prevented. In order to achieve size reduction, in this example, the gap factual solder joining thickness) between the metal electrode portion 11 of the circuit board 10 and the metal electrode portion 6 of the semiconductor module 13 is not less than 20 μm but less than 100 μm, and in this range, the slopes 8 act effectively. As the angle θ of the slopes 8 is increased, the solder joining property is more improved. But meanwhile, it is necessary to prevent the inside terminal 5 (frame) from being exposed from the sealing material 7. In actual module designing, θ may be not less than 1° and not larger than 10°. If θ is larger than 10°, it is necessary to prevent the terminal 5 from being exposed, so that the degree of freedom in module designing is lowered. More preferably, θ is not less than 3° and not larger than 8°.

The molded and sealed semiconductor module 13 has the slopes 8 on the joining-surface side opposite to the circuit board 10, and therefore reduction gas readily enters there and a volatile component from the solder material is readily expelled. Thus, Joining fault can be prevented in each joining method. Further, when the underfill material 12 is injected into the narrow gap at the joining part after joining, the underfill material 12 readily enters the gap, so that occurrence of voids can be prevented.

### Embodiment 2

FIG. 21 and FIG. 22 are side sectional views showing a semiconductor device according to embodiment 2. Regarding the slope, as shown in FIG. 21, a slope 14 may be provided such that an upper surface of the sealing material 7 is formed into a curved-surface shape. In FIG. 21, an example in which the slope 14 having a curved-surface shape is provided on the left side is shown. However, a slope having a curved-surface shape may be provided on the right side. In a case of providing slopes having curved-surface shapes on the both sides of the left side and right side, the slopes may be asymmetric between left and right or may be symmetric between left and right. FIG. 23 is a plane view of the sealing material 7 in FIG. 22, as seen from a direction A. As shown in FIG. 23, a plurality of slits (grooves) 16 for allowing contamination to readily flow in a constant direction may be provided on an upper surface 15 of the sealing material 7 in which the slopes 8 are provided. As described above, the upper surface of the sealing material 7 in which the slope is provided is formed into a curved-surface shape or the slits are provided on the upper surface of the sealing 7, whereby contamination incidentally accumulated at the solder joining part can be efficiently expelled. In a case of performing production by using a die having slopes as shown in FIG. 10 to FIG. 13, the slopes 8a, 8b of the upper die 19 are formed into curved-surface shapes ox the slopes 8a, 8b are formed into slit shapes. Whereby the slopes 14 having curved-surface shapes or the slits 16 can be formed.

### Embodiment 3

An upper surface of the slope 8 of the sealing material 7 may be coped by smoothing treatment so that a surface roughness Ra thereof becomes not larger than 0.5 μm. JIS prescribes definition and indication of the arithmetic average roughness (Ra), the maximum height (Ry), the 10-point average roughness (Rz), the recess-projection average interval (Sm), the average interval of local peaks (s), and the load length ratio (tp), as parameters representing the surface roughness of an industrial product. The surface roughness Ra is an arithmetic average value at each part randomly extracted from the surface of an object. By performing s ng treatment on the upper surface of the sealing material 7 as described above, the recess-projection size is reduced, so that contamination is not accumulated and favorable soldering property is obtained.

Although the disclosure is described above in terms of various exemplary embodiments and implementations, it should be understood that the various features, aspects, and functionality described in one or more of the individual embodiments are not limited in their applicability to the particular embodiment with which they are described, but they can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

3 semiconductor element
4 first joining material
5 terminal
6 first metal electrode portion
7 sealing material
8 slope
9 second joining material
10 circuit board
11 second metal electrode portion
16 slit

1.-7. (canceled)

8. A semiconductor device, wherein
a first metal electrode portion is provided on an upper surface side of a semiconductor element,
the semiconductor element is sealed by a sealing material such that an upper surface of the first metal electrode portion is exposed,
the upper surface of the first metal electrode portion is connected via a second joining material to a lower surface of a second metal electrode portion formed at a lower surface of a circuit board, and
a slope is provided on an upper surface of the sealing material so that a vertical-direction height at the first metal electrode portion is the largest.

9. The semiconductor device according to claim 8, wherein
the first metal electrode portion is provided on an upper surface thereof of a terminal that is joined via a first joining material to an upper surface of the semiconductor element,
the terminal and the semiconductor element are sealed by the sealing material, and
the slope is constituted so that a vertical-direction height at an end of the sealing material is low.

10. The semiconductor device according to claim 9, wherein
solder materials are used as the first joining material and the second joining material, and a melting point of the first joining material is higher than a melting point of the second joining material.

11. The semiconductor device according to claim 8, wherein
an angle of the slope with respect to a horizontal direction is not less than 1° and not lager than 10°.

12. The semiconductor device according to claim 8, wherein
the upper surface of the sealing material in which the slope is provided is formed into a curved-surface shape.

13. The semiconductor device according to claim 8, wherein
a plurality of slits are provided on the upper surface of the sealing material in which the slope is provided.

14. The semiconductor device according to claim 8, wherein
the upper surface of the sealing material is coped by smoothing treatment so that an arithmetic average roughness which is an index of a surface roughness on the upper surface of the sealing material in which the slope is provided is not larger than 0.5 μm.

15. A method for producing a semiconductor device, the method comprising the steps of:
placing, at an inside between a lower die and an upper die having a slope at an upper inner surface thereof, such a unit that a terminal having a first metal electrode portion at an upper surface thereof is joined via a first joining material to an upper surface of a semiconductor element;
injecting a sealing material to the inside between the lower die and the upper die; and
removing the upper die and the lower die and connecting an upper surface of the first metal electrode portion via a second joining material to a lower surface of a second metal electrode portion formed at a lower surface of a circuit board.

16. The semiconductor device according to claim 9, wherein
an angle of the slope with respect to a horizontal direction is not less than 1° and not lager than 10°.

17. The semiconductor device according to claim 10, wherein
an angle of the slope with respect to a horizontal direction is not less than 1° and not lager than 10°.

18. The semiconductor device according to claim 9, wherein
the upper surface of the sealing material in which the slope is provided is formed into a curved-surface shape.

19. The semiconductor device according to claim 10, wherein
the upper surface of the sealing material in which the slope is provided is formed into a curved-surface shape.

20. The semiconductor device according to claim 11, wherein
the upper surface of the sealing material in which the slope is provided is formed into a curved-surface shape.

21. The semiconductor device according to claim 16, wherein
the upper surface of the sealing material in which the slope is provided is formed into a curved-surface shape.

22. The semiconductor device according to claim 17, wherein
the upper surface of the sealing material in which the slope is provided is formed into a curved-surface shape.

23. The semiconductor device according to claim 9, wherein
a plurality of slits are provided on the upper surface of the sealing material in which the slope is provided.

24. The semiconductor device according to claim 10, wherein
a plurality of slits are provided on the upper surface of the sealing material in which the slope is provided.

25. The semiconductor device according to claim 11, wherein
a plurality of slits are provided on the upper surface of the sealing material in which the slope is provided.

26. The semiconductor device according to claim 12, wherein
a plurality of slits are provided on the upper surface of the sealing material in which the slope is provided.

27. The semiconductor device according to claim 16, wherein
a plurality of slits are provided on the upper surface of the sealing material in which the slope is provided.
